(19) United States
(12) Patent Application Publication
(10) Pub. No.: US 2025/0262640 A1
(43) Pub. Date: Aug. 21, 2025

(54) Masking Systems

(71) Applicant: Chromalloy Gas Turbine LLC, Palm Beach Gardens, FL (US)

(72) Inventors: Zachary Hopkins, San Diego, CA (US); Zachary Oras, Riverview, FL (US); Logan Mitchell, Tampa, FL (US); James Whitton, East Burke, VT (US)

(21) Appl. No.: 18/443,244

(22) Filed: Feb. 15, 2024

(51) Int. Cl. B05C 21/00; B33Y 80/00; C23C 16/04; F01D 5/28

(52) U.S. Cl. CPC B05C 21/005; C23C 16/042; F01D 5/288; B33Y 80/00; F05D 2230/90

(57) ABSTRACT

A masking system for selectively masking a component includes a first shell half and a second shell half. The second shell half is configured to be secured to the first shell half such that at least a portion of the first shell half overlaps the second shell half when the component is retained by the masking system. A protrusion extends from one of the first shell half and the second shell half. The protrusion is configured to cover an edge of the component.

### CROSS REFERENCE TO RELATED APPLICATIONS

None.

### FIELD OF THE DISCLOSURE

The disclosure relates generally to the field of making systems. More specifically, the disclosure relates to multi-component masking systems for selectively masking a component.

### SUMMARY

The following presents a summary of the invention in order to provide a basic understanding of some aspects of the invention. This summary is not an extensive overview of the invention. It is not intended to identify critical elements of the invention or to delineate the scope of the invention. Its sole purpose is to present some concepts of the invention in a simplified form as a prelude to the more detailed description that is presented elsewhere herein.

In an aspect of the disclosure, a masking system for selectively masking a component is provided. The masking system has a first shell half and a second shell half. The second shell half is configured to be secured to the first shell half such that at least a portion of the first shell half overlaps the second shell half when the component is retained by the masking system. A protrusion extends from one of the first shell half and the second shell half. The protrusion is configured to cover an edge of the component.

In an aspect, according to any one of the preceding aspects, the protrusion is removable.

In an aspect, according to any one of the preceding aspects, the masking system is configured to retain the component for a coating process.

In an aspect, according to any one of the preceding aspects, a distribution of coating on the component is associated with a profile of the protrusion.

In an aspect, according to any one of the preceding aspects, the first shell half has a first tab, and the second shell half has a second tab that corresponds to the first tab when the first shell half is brought into contact with the second shell half.

In an aspect, according to any one of the preceding aspects, the masking system includes a fastener extending through each of the first tab and the second tab.

In an aspect, according to any one of the preceding aspects, the masking system includes interlocking clips extending through each of the first tab and the second tab.

In an aspect, according to any one of the preceding aspects, the masking system is additively manufactured.

In an aspect, according to any one of the preceding aspects, the component is a component of a gas turbine.

In an aspect, according to any one of the preceding aspects, the component is a gas turbine blade, and the edge is a trailing edge of the gas turbine blade.

In an aspect, according to any one of the preceding aspects, the masking system is configured to mask at least a dovetail of the gas turbine blade.

In an aspect, according to any one of the preceding aspects, the first shell half includes a first shelf, and the second shell half includes a second shelf. Each of the first shelf and the second shelf are configured to contact the component.

In an aspect, according to any one of the preceding aspects, the masking system includes a mounting portion for mounting the masking system to a surface.

In an aspect, according to any one of the preceding aspects, the mounting portion is removably coupled to one of the first shell half and the second shell half.

In an aspect of the disclosure, an additively manufactured masking system for selectively masking a blade of a gas turbine for a coating process is provided. The masking system includes a first shell half having a wall corresponding to a suction side of the blade. The masking system includes a second shell half having a wall corresponding to a pressure side of the blade. The masking system includes a protrusion extending from one of the first shell half and the second shell half. A distribution of coating on the blade is associated with a profile of the protrusion.

In an aspect, according to any one of the preceding aspects, the protrusion is removable.

In an aspect, according to any one of the preceding aspects, the protrusion has a generally spherical shape.

In an aspect, according to any one of the preceding aspects, the protrusion has a generally trapezoidal shape.

In an aspect of the disclosure, a masking system for selectively masking a component is disclosed. The masking system includes a first shell having a first cover and a first tab. The first cover has at least a first recess and a first peak. Each of the first recess and the first peak correspond to the component at a first side thereof. The masking system has a second shell having a second cover and a second tab. The second cover has at least a second recess and a second peak. Each of the second recess and the second peak correspond to the component at a second side thereof. The second side opposes the first side.

In an aspect, according to any one of the preceding aspects, the component is a gas turbine vane.

### BRIEF DESCRIPTION OF THE DRAWINGS

Illustrative embodiments of the present disclosure are described in detail below with reference to the attached drawing figures and wherein:

FIG. 1 is a perspective view of a turbine blade.

FIG. 2 is a perspective view of a turbine vane.

FIG. 3 is a perspective view of a masking system, according to an aspect of the disclosure.

FIGS. 4 and 5 are additional perspective views of the masking system of FIG. 3.

FIG. 6 is a perspective view of a first shell half of the masking system of FIG. 3.

FIG. 7 is a perspective view of a second shell half of the masking system of FIG. 3.

FIG. 8 is a perspective view of a turbine blade seated within the masking system of FIG. 3, according to an aspect of the disclosure.

FIGS. 9 and 10 are perspective views of a masking system, according an aspect of the disclosure.

FIG. 11 is a perspective view of a first shell half of the masking system of FIG. 9.

FIG. 12 is a perspective view of a second shell half of the masking system of FIG. 9.

FIGS. 13 and 14 are perspective views of a masking system, according to an aspect of the disclosure.

FIG. 15 is an exploded view of the masking system of FIG. 13.

FIGS. 16 and 17 are perspective views of a first shell half and a second shell half of the masking system of FIG. 13.

FIG. 18 is a perspective view of the second shell half of the masking system of FIG. 13.

FIGS. 19 and 20 are perspective views of a mounting handle of the masking system of FIG. 13.

FIG. 21 is a perspective view of a protrusion of the masking system of FIG. 13.

FIG. 22A is a perspective view of a second shell of a masking system of FIG. 22C, according to an aspect of the disclosure.

FIG. 22B is a perspective view of a first shell of the masking system of FIG. 22C, according to an aspect of the disclosure.

FIG. 22C is a perspective view of a turbine vane seated within a masking system, according to an aspect of the disclosure.

FIG. 23A is another perspective view of the first shell of the masking system of FIG. 22C.

FIG. 23B is another perspective view of the second shell of the masking system of FIG. 22C.

FIGS. 24A and 24B are perspective views of a top cover and a bottom cover of the masking system of FIG. 22C, respectively.

FIG. 25 is a side view of interlocking clips with the turbine blade seated within the masking system of FIG. 3.

FIG. 26 is a schematic view of the interlocking clips of FIG. 25.

FIG. 27 is a flowchart illustrating a method of making and using the cover of FIG. 3, FIG. 9, FIG. 13, and FIG. 22C.

### DETAILED DESCRIPTION

A gas turbine engine typically includes a multi-stage compressor coupled to a multi-stage turbine via an axial shaft. Air enters the gas turbine engine through the compressor where its temperature and pressure are increased as it passes through subsequent stages of the compressor. The compressed air is then directed to one or more combustors where it is mixed with a fuel source to create a combustible mixture. This mixture is ignited in the combustors to create a flow of hot combustion gases. These gases are directed into the turbine causing the turbine to rotate, thereby driving the compressor. The output of the gas turbine engine can be mechanical thrust via exhaust from the turbine or shaft power from the rotation of an axial shaft, where the axial shaft can drive a generator to produce electricity.

The compressor and turbine each include a plurality of rotating blades and stationary vanes having an airfoil extending into the flow of compressed air or flow of hot combustion gases. Each blade or vane has a particular set of design criteria which must be met to provide the necessary work to the flow passing through the compressor and the turbine. However, due to the severe nature of the operating environment, especially in the turbine, it is often necessary to cool these blades and vanes. The blades and vanes often utilize complex internal cooling passageways in order to maximize the efficiency of cooling fluid passing therethrough. The internal cooling passageways are often operably linked to external cooling holes in the blade or vane which, during gas turbine engine operation, expel the cooling fluid from the internal cooling passageway to cool the blade or vane.

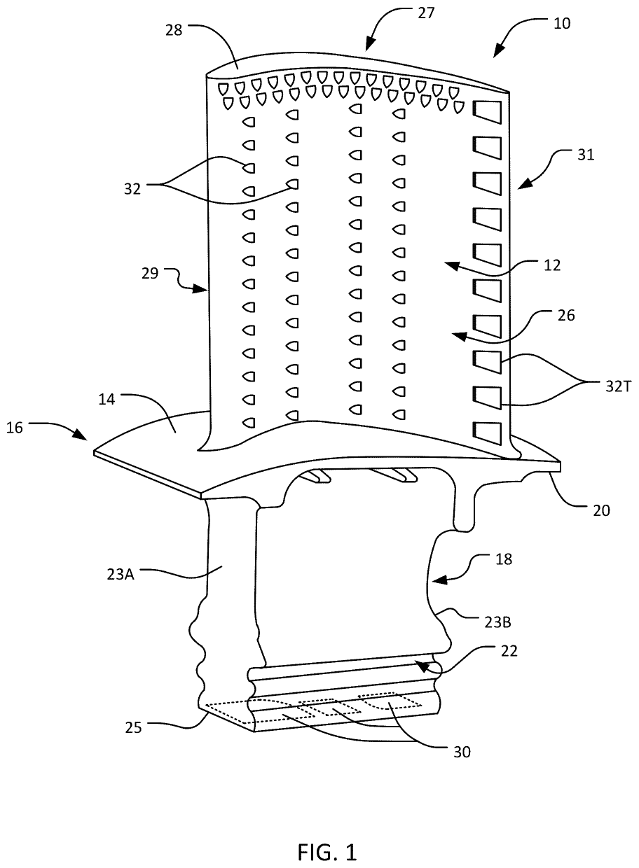

FIG. 1 shows a gas turbine component that is a blade 10. The blade 10 generally includes an airfoil 12 extending from a top or gas path side surface 14 of a platform 16 and a root fixing portion or “dovetail” 18 depending from an undersurface 20 of the platform 16. The dovetail 18 may include one or more serrations or tangs 22 that extend laterally from one side 23A of the dovetail 18 to an opposing side 23B of the dovetail 18. The dovetail 18 may terminate at a terminal or bottom wall 25 that may span between the dovetail sides 23A and 23B. The dovetail 18, including the tangs 22 and the bottom wall 25 thereof, may be adapted for interlocking engagement in a corresponding slot defined in the periphery of a hub of a turbine rotor.

The airfoil 12 may have a pressure side 26, a suction side 27 opposite the pressure side 26, a tip 28, a leading edge 29, and a trailing edge 31. The tip 28 may include or may be configured to interact with a shroud. The shroud may be provided at the tip 28 of each blade 10, or may be a stationary ring including one or more circumferentially extending sections each connected to the gas turbine casing. The shroud(s) may be configured to seal the gap between the tip 28 of the blade 10 and stationary components (e.g., stators) of the turbine, and thereby, may reduce leakage flow between the rotating and stationary components. The airfoil 12, e.g., the pressure side 26 thereof, may come into contact with combustion gases that are at an extremely high temperature. The airfoil 12 or portions thereof may therefore be coated with heat-resistant, wear-resistant, and/or other coatings. During operation, the tip 28 may rub against the tip shroud, and the tip 28 may therefore additionally or alternately be coated with wear-resistant coatings. In like fashion, one or more other portions of the blade 10 may be coated with different materials depending on the environment in which these portions are located and the stresses encountered thereby.

The bottom wall 25 of the dovetail 18 may include one or more air inlet apertures 30. Further, one or more portions of the blade 10 may include cooling holes 32 for cooling the blade 10 during operation. The cooling holes 32 may be provided on one or more surfaces of the airfoil 12, such as the pressure side 26, the suction side 27, the tip 28, the leading edge 29, the trailing edge 31, or a combination thereof. The cooling holes 32 may be circular cooling holes, diffused (e.g., angled) cooling holes, cooling slots, or take on one or more other regular or irregular shapes. Cooling gas may pass through internal cooling channels (not illustrated for ease of description) in the blade 10 and emerge from the cooling holes 32 to create a blanket of thin film over the outer surface of the airfoil 12, thus preventing direct contact of the hot gases and the surfaces of the blade 10. For example, the illustrated blade 10 has air inlet apertures 30 in the bottom wall 25 of the dovetail 18 and cooling holes 32 on the pressure side 26 of the airfoil 12. The blade 10, including the airfoil 12 thereof, may include hollow interior passages for the passage of cooling air, for example, but not limited to, from air inlet apertures 30 to cooling holes 32. Thus, cooling air may be bled from the compressor and channeled into the air inlet apertures 30. This air may exit out the cooling holes 32 to cool one or more portions of the blade 10 during operation. One having skill in the art will understand that different blades may have differing cooling schemes and that the inlet apertures 30 and cooling holes 32 in FIG. 1 are merely exemplary and not intended to be independently limiting.

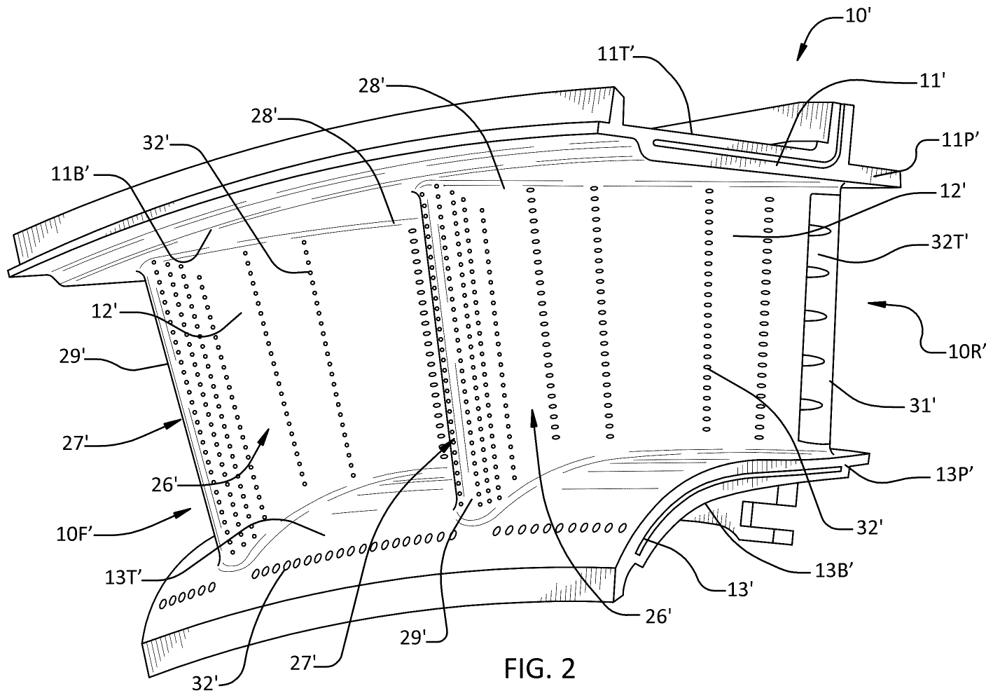

FIG. 2 shows a gas turbine vane 10′. Where the blade 10 may be designed as a rotating or moving component of the gas turbine engine, the vane 10′ may be intended as a stationary component of the gas turbine engine. The vane 10′ generally includes one or more airfoils 12′ extending between a bottom surface 11B′ of a top platform 11′ and a top surface 13T′ of a bottom platform 13′. The airfoils may generally extend from a front or leading end 10F′ of the top platform 11′ and bottom platform 13′ to a rear or trailing end 10R′ of the top platform 11′ and bottom platform 13′. The top platform 11′ and bottom platform 13′ may be adapted for interlocking engagement with a corresponding portion of the gas turbine engine (e.g., a corresponding slot defined in an area of the gas turbine engine adjacent the area of the gas turbine engine where one or more blades 10 are located). The vane 10′ may include one or more non-gas path surfaces, such as a top surface 11T′ of the top platform 11′, a perimeter 11P′ of the top platform 11′, a bottom surface 13B′ of the bottom platform 13′, and a perimeter 13P′ of the bottom platform 13′. These non-gas path surfaces may, in some aspects, have features for securing the vane 10′ to other parts of gas turbine engine.

Each of the airfoils 12′ may have a pressure side 26′, a suction side 27′ opposite the pressure side 26′, a tip 28′ engaged with the bottom surface 11B′, a leading edge 29′, and a trailing edge 31′. The top platform 11′ and bottom platform 13′ may be a part of a stationary ring including one or more circumferentially extending sections each connected to the gas turbine casing. The airfoils 12′, e.g., the pressure sides 26′ thereof, may come into contact with combustion gases that are at an extremely high temperature. The airfoils 12′ or portions thereof may therefore be coated with heat-resistant, wear-resistant, and/or other coatings. In like fashion, one or more other portions of the vane 10′ may be coated with different materials depending on the environment in which these portions are located and the stresses encountered thereby.

Like the blade 10, one or more portions of the vane 10′ may include cooling holes 32′ for cooling the vane 10′ during operation. The cooling holes 32′ may be provided on one or more surfaces of the airfoils 12′, such as the pressure side 26′, the suction side 27′, the leading edge 29′, the trailing edge 31′ (e.g., cooling holes 32T′), or a combination thereof. The cooling holes 32′ may alternately or additionally be located on other portions of the vane 10′, such as along the top surface 13T′ of the bottom platform 13′. The cooling holes 32′ may be circular cooling holes, diffused (e.g., angled) cooling holes, cooling slots, or take on one or more other regular or irregular shapes. Cooling gas may pass through internal cooling channels (not illustrated for ease of description) in the vane 10′ and emerge from the cooling holes 32′ to create a blanket of thin film over outer surfaces of the vane 10′, e.g., over the airfoils 12′, the bottom surface 11B′, the top surface 13T′, et cetera, thus preventing direct contact of the hot gases and those surfaces. For example, the illustrated vane 10′ may have air inlet apertures (not illustrated for ease of description) in the top platform 11′ and/or the bottom platform 13′. The vane 10′, including the airfoils 12′ thereof, may include hollow interior passages for the passage of cooling air, for example, but not limited to, to cooling holes 32′. Thus, cooling air may be bled from the compressor and channeled through to the cooling holes 32′. This air may exit out the cooling holes 32′ to cool one or more portions of the vane 10′ during operation. One having skill in the art will understand that different vanes 10′ may have differing cooling schemes and that the inlet apertures and cooling holes 32′ in FIG. 2 are merely exemplary and not intended to be independently limiting.

A gas turbine component, such as the blade 10 or the vane 10′, may be manufactured using investment casting, also referred to in the art as lost-wax processing. The investment casting process may involve making a precise negative die of the blade shape that is filled with wax to form the blade or vane shape. If the component, such as the blade 10 or the vane 10′, is hollow and has interior cooling passages, a ceramic core in the shape of the cooling passages may be inserted into the middle. The wax blade or vane may be coated with a heat-resistant material to make a shell, and then that shell may be filled with a metal alloy.

Once cast, the blade 10 or the vane 10′ may undergo one or more finishing processes to prepare the blade 10 or vane 10′ for operation. The finishing processes may ensure that the blade 10 or the vane 10′ has the required aerodynamic profile, which may impact engine efficiency and fuel consumption. The finishing processes may also make the blade 10 or vane 10′ more resistant to fatigue, and thereby increase the lifespan of the blade 10 or vane 10′. Some finishing processes may reduce the maintenance requirements associated with the blade 10 or vane 10′.

Finishing the blade 10 or vane 10′ may include coating one or more surfaces of the blade 10 or vane 10′. For example, one or more surfaces of the blade 10 or vane 10′ may be blasted with abrasive media to configure these surfaces to accept coatings, and thereafter, heat-resistant, wear-resistant, and/or other coatings may be applied to these surfaces of the blade 10 or vane 10′. Some non-limiting examples of coating methods which may be used in the finishing processes include low pressure plasma spraying methods, electron beam physical vapor deposition methods, pack aluminide methods, vapor phase aluminide methods, chromide coating methods, ceramic or metallic coating method et cetera. Finishing the blade 10 or vane 10′ may also include deburring and breaking sharp edges, polishing one or more surfaces of the blade 10 or vane 10′ to remove excess material, welding, brazing, or otherwise associating another feature with the blade 10 or vane 10′, machining one or more surfaces of the blade 10 or vane 10′, coating one or more surfaces of the blade 10 or vane 10′, and so on. The term “finishing” and the phrase “surface finishing”, as used herein, includes any one of the one or more processes that may be used to alter a manufactured component to cause it to achieve a certain property. For example, finishing the blade 10 or vane 10′ includes the one or more processes undergone by the blade 10 or vane 10′ (e.g., media blasting, brazing, coating, machining, et cetera) after it is cast to prepare the blade 10 or vane 10′ for operation in a gas turbine.

Many of the coatings applied in a finishing process are intended to cover only a specific part or portion of the gas turbine component. For example, for the blade 10, a heat-resistant coating may be intended to cover the pressure side 26 of the airfoil 12 while avoiding cooling holes 32T arranged near the trailing edge 31. If the protective coating is unintentionally applied to cooling holes 32T, the protective coating may clog the cooling holes 32T and preclude cooling air from exiting cooling holes 32T. Similarly, for the vane 10′, a heat-resistant coating may be intended to cover some or all of the one or more airfoils 12′ while avoiding the top platform 11′ and bottom platform 13′. As another example, a finishing process, such as a media blasting process, may only be intended to affect the airfoil 12 of blade 10, and not to other portions thereof, such as the dovetail 18, as media blasting these portions may negatively impact performance of blade 10. To ensure that a process, such as a finishing process, impacts only a particular portion or portions of a component, such as blade 10 or vane 10′, one or more masking systems may be used to mask, cover, or protect the portions of the component that are not intended to be impacted by the finishing process.

Some finishing processes involve diffusing a coating material into one or more surfaces of a component at a high temperature over an extended period of time, such as low-pressure plasma spray methods, electron beam physical vapor deposition methods, aluminum powder diffusion, et cetera. The medium used to coat the component may be a gas, and as such, any gap or opening between the masking system and the component may allow contact between the coating and the component. To prevent such gaps or openings from allowing the finishing process from unintentionally coating an area of the component, a slurry of material, e.g., an aluminum oxide material, may be packed in between the masking system and component. The slurry of material may deform to cover those areas of the component that would otherwise be exposed to the medium by the gaps or openings of the masking system. To be able to pack the slurry between the masking system and the component held therein, some masking systems may be designed specifically for the injection of slurry, e.g., include injection ports for the insertion of slurry into the masking system.

Some masking systems used to shield portions of components, e.g., gas turbine components such as the blade 10 or the vane 10′, during a finishing process are constructed of a polymer-based material. Masking systems made of polymer-based material may be relatively cheap and may be easier to manufacture compared to metallic masking systems. However, polymer-based masking systems may be susceptible to damage when subjected to finishing processes involving high-temperatures, e.g., a high-temperature coating process. A high temperature coating process may involve heating one or more materials to temperatures of, for example, between about 260° C. to about 320° C., and up to about 1100° C. A masking system constructed of a polymer-based material, when heated to such temperatures, may deform, distort, or otherwise lose its shape during the high-temperature coating process, which may result in portions of the component undergoing the coating process to unintentionally receive the coating. For this reason, masking systems made of polymer-based materials are typically ruled out for high-temperature processes, including high-temperature coating processes.

To withstand the high temperatures that may be encountered during a finishing process, some masking systems are manufactured from metal. For example, masking systems may be manufactured using sheet metal fabrication techniques. It may be unduly laborious and time-consuming to fabricate a masking system using sheet metal fabrication techniques. In some cases, sheet metal fabrication of a masking system may take about two to four weeks. Furthermore, masking systems constructed from sheet metal may not be suitably durable, and may deform during the high-temperature process (e.g., a high-temperature coating process) and cause damage to the component undergoing the high-temperature process.

Masking systems may also be manufactured using investment casting techniques. Masking systems manufactured using investment casting techniques may be more durable than masking systems manufactured using sheet metal fabrication techniques, and may be reused for a plurality of finishing processes. Further, a large number of masking systems may be made using investment casting for relatively low cost after the initial casts have been formed. However, designing and constructing these casts is a lengthy process involving a long lead time, e.g., around twelve weeks or more. Furthermore, if a given design profile for a masking system is used and found to be inadequate, i.e., the masking system formed from that design profile does not properly shield the intended areas of the gas turbine component, then a large amount of time and effort must be expended to restructure the design profile and fabricate a new masking system.

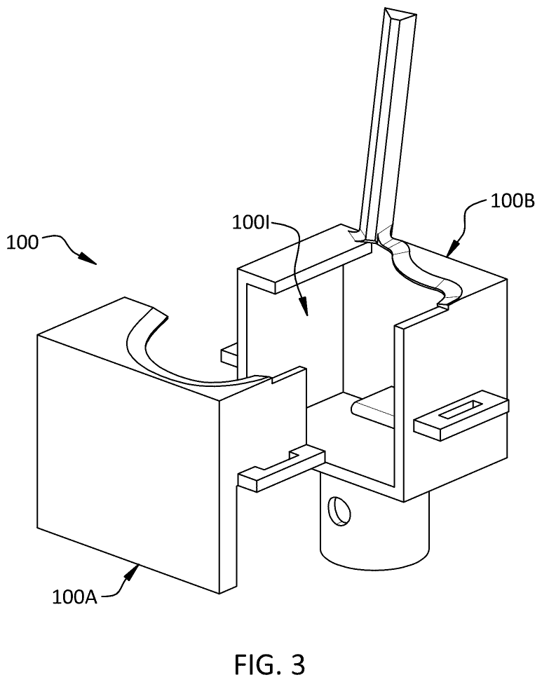

FIGS. 3-23 show masking systems for masking components (e.g., gas turbine or other components) undergoing one or more finishing processes. The finishing process may be a high-temperature processes, such as a high-temperature coating process. Specifically, FIGS. 3-7, 8-11, and 12-20 respectively show a masking system 100, a masking system 200, and a masking system 300 for masking blade 10 undergoing a finishing process (e.g., a high-temperature coating process), and FIGS. 21-23 show a masking system 400 for masking vane 10′ undergoing a finishing process (e.g., a high-temperature coating process).

In aspects of the disclosure, one or more of masking system 100, masking system 200, masking system 300, and masking system 400 may be additively manufactured as discussed herein. In some examples, one or more of the masking system 100, masking system 200, masking system 300, and/or masking system 400 may be additively manufactured and employed to mask a component undergoing a high-temperature process. Alternately or in addition, one or more of the masking system 100, masking system 200, masking system 300, and/or masking system 400 may be used as prototypes for masking systems that are subsequently investment casted or fabricated using other techniques. For example, a prototype of masking system 100 may be used to mask blade 10 undergoing a high-temperature process, and the protype may be tested, e.g., using spectrometer, blue light, or other methods now known or subsequently developed, to determine the viability of masking system 100. One or more features of the protype may be redesigned to improve one or more characteristics (e.g., masking characteristics, durability, usability, et cetera) of masking system 100. Once the design of an additively manufactured masking system 100 (and/or of the masking system 200, masking system 300, or masking system 400) is finalized, the additively manufactured masking system 100 may be used to mask blade 10 undergoing one or more high-temperature processes and may also be used to facilitate fabrication of the masking system 100 using other techniques (e.g., investment casting or other methods now known or subsequently developed). For instance, a masking system 100 that is additively manufactured may be used to fabricate production tooling for manufacturing masking systems 100 using investment casting techniques.

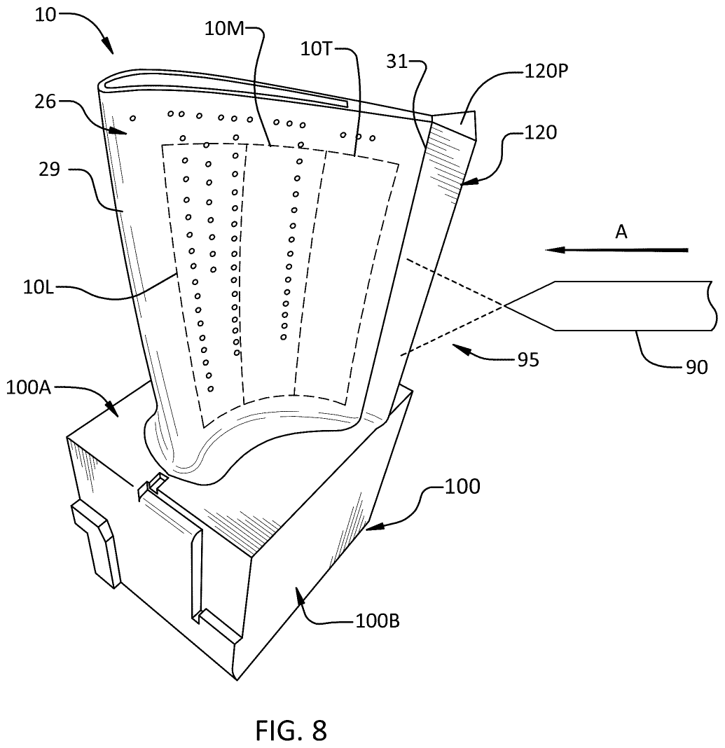

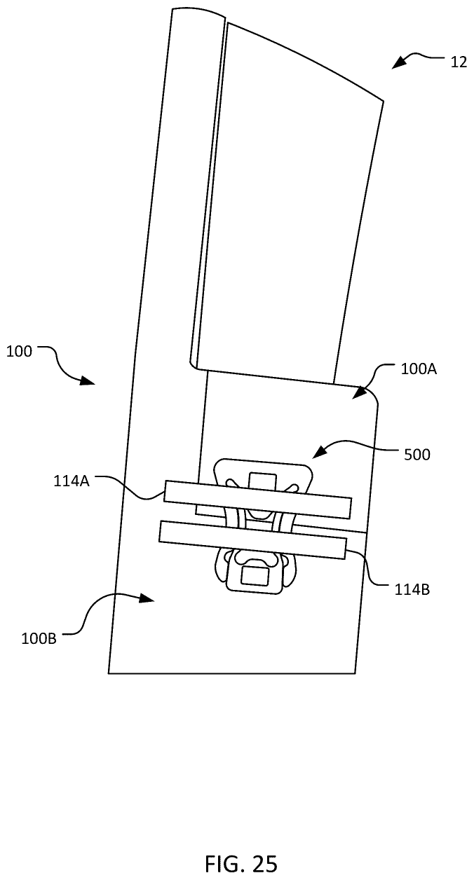

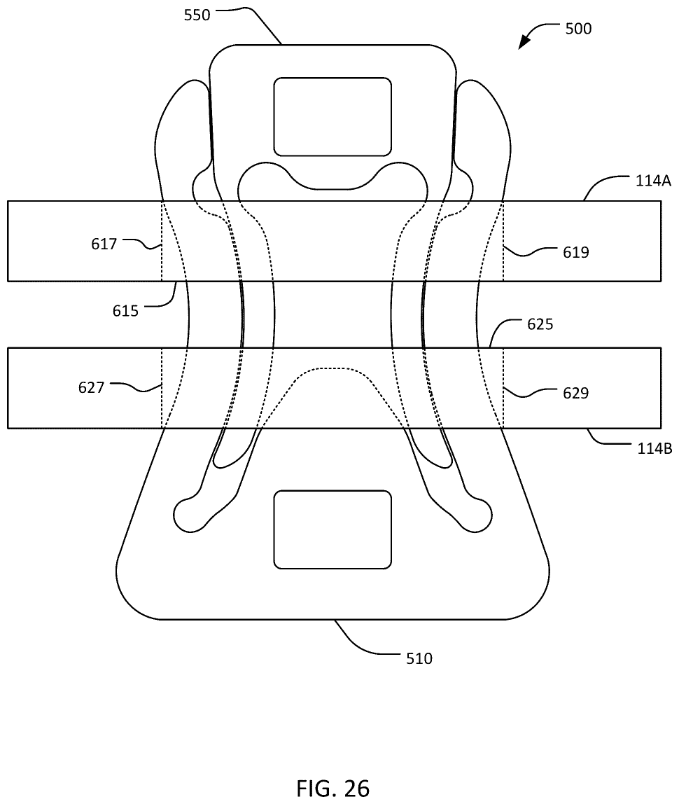

Focus is directed to FIGS. 3-8 which show masking system 100 for selectively masking blade 10 undergoing a high-temperature process. In some examples, masking system 100 may shield or otherwise protect one or more non-gas path surfaces of blade 10. In non-limiting aspects of the disclosure, masking system 100 may have a first shell half 100A and a second shell half 100B. First shell half 100A and second shell half 100B may be brought together and secured to each other to encapsulate a portion of the blade 10 (see FIG. 8) within an interior 100I of first shell half 100A and second shell half 100B. For example, a fastener may be inserted through tabs associated with the first shell half 100A and second shell half 100B as discussed herein to securely retain blade 10 within interior 100I. One example of a fastener usable for securing first shell half 100A and second shell half 100B may be the interlocking clips 500 depicted in FIGS. 25 and 26.

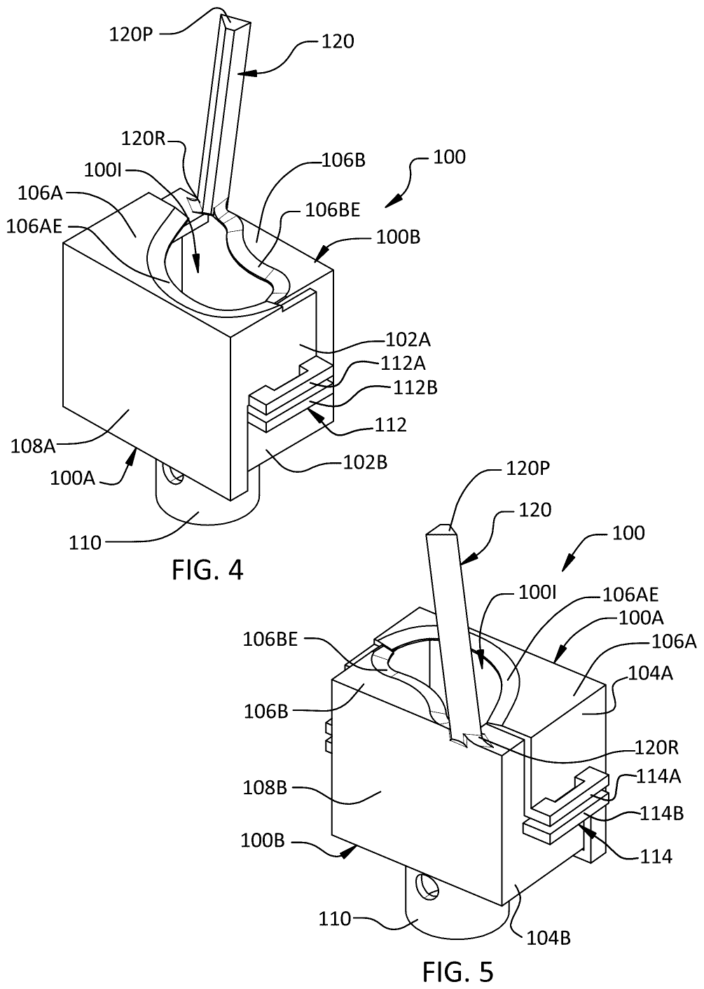

In some examples, first shell half 100A and second shell half 100B may overlap or cover each other when they are brought into contact with each other. For instance, first shell half 100A may have a first side wall 102A (see FIG. 4) and a second side wall 104A (see FIG. 5) that respectively overlap a first side wall 102B (see FIG. 4) and a second side wall 104B (see FIG. 5) of the second shell half 100B when first shell half 100A and second shell half 100B are brought into contact with each other. Overlapping side walls may provide for a suitable seal as the blade 10 retained within the masking system 100 undergoes a finishing process, such as a coating process. An improper seal may allow coating material to penetrate the masking system 100 and improperly coat portions of the blade 10.

The masking system 100 may also have a protrusion 120. The protrusion 120 may extend from the second shell half 100B as illustrated and/or the first shell half 100A. In the illustrated embodiment, the protrusion 120 may extend along and mask the trailing edge 31 of blade 10 while blade 10 is seated within masking system 100 (see FIG. 8).

Focus is directed to FIGS. 4-7, which show the masking system 100 in greater detail according to some aspects of the disclosure. The masking system 100 may cover (e.g., shield or envelope) one or more portions of a gas turbine component, such as the blade 10, and protect the one or more portions of the blade 10 from inadvertently being impacted by a finishing process, such as coating. In the embodiment illustrated in FIG. 8, the masking system 100 is shown covering and protecting the dovetail 18 and the trailing edge 31 of a blade 10, while leaving the airfoil 12 thereof substantially exposed. In other examples of the disclosure, the masking system may protect one or more other surfaces of the blade 10 or another component (such as a gas turbine vane or other component).

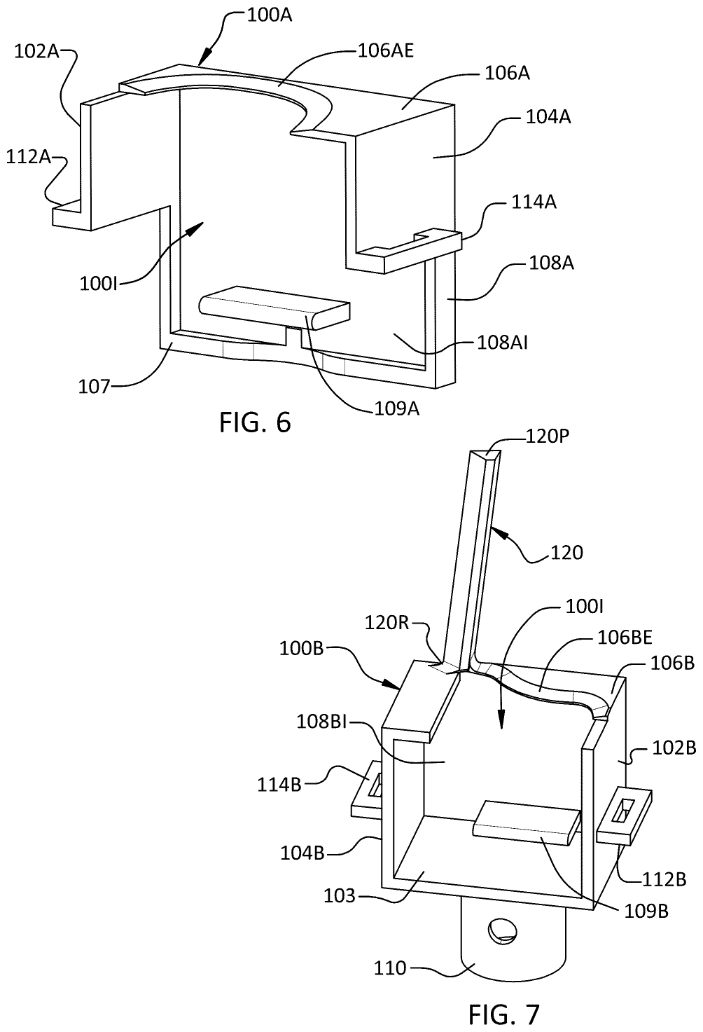

As best shown in FIG. 6, the first shell half 100A may have the first side wall 102A, the second side wall 104A opposing first side wall 102A, a top wall 106A extending laterally between first side wall 102A and second side wall 104A, and an end wall 108A extending vertically between first side wall 102A and second side wall 104A. The top wall 106A may have an edge 106AE. The shape of edge 106AE may generally correspond to a profile of the airfoil 12, e.g., on the suction side 27 of the blade 10. In some aspects, edge 106AE may be tapered.

The first shell half 100A may include a lip 107 which extends from one or more of first side wall 102A, second side wall 104A, top wall 106A, and/or end wall 108A. The first shell half 100A may further include a shelf 109A that extends from an interior 108AI of end wall 108A. The shelf 109A may assist in retaining the component within the masking system 100. For example, the shelf 109A may contact the dovetail 18 of a blade 10 seated in the interior 100I.

The second shell half 100B (see FIG. 7) may have a first side wall 102B, a second side wall 104B opposing first side wall 102B, a top wall 106B, an end wall 108B extending vertically between first side wall 102B and second side wall 104B, a bottom wall 103 extending laterally between first side wall 102B and second side wall 104B, and a mounting portion 110 extending from bottom wall 103. The top wall 106B may have an edge 106BE that has a shape which generally corresponds to a profile of the blade 10. For example, the shape of edge 106BE may generally correspond to a profile of the airfoil 12, e.g., on the pressure side 26 of the blade 10. In some aspects, edge 106BE may be tapered.

The second shell half 100B may further include protrusion 120 having a profile 120P. The protrusion 120 may extend from a protrusion base 120R located on top wall 106B. In some aspects, the protrusion base 120R may be located proximate, at, or along the edge 106BE. The second shell half 100B may further include a shelf 109B that extends from an interior 108BI of end wall 108A. The shelf 109B may assist in retaining the component within the masking system 100. For example, the shelf 109B may contact the dovetail 18 of a blade 10 seated in the interior 100I.

The mounting portion 110 may be usable for securing the masking system 100 to a stabilizing structure (not shown, e.g., a table, a tool, a vice, et cetera) to prevent motion of masking system 100 while the blade 10 retained therein undergoes a finishing process. The mounting portion 110 may have any suitable arrangement and number of openings, slots, apertures, et cetera, to allow for the masking system 100 to be coupled to the stabilizing structure.

Connecting members or tabs may be provided on each of the first shell half 100A and second shell half 100B to allow first shell half 100A to be secured to second shell half 100B while blade 10 is retained within masking system 100. In some examples, first shell half 100A may have a first tab 112A (FIG. 6) that extends from first side wall 102A and the second shell half 100B may have a third tab 112B (FIG. 7) that extends from first side wall 102B. First tab 112A of first shell half 100A may correspond to third tab 112B of second shell half 100B when first shell half 100A and second shell half 100B are brough into contact with each other. In some examples, first shell half 100A may further include a second tab 114A that extends from second side wall 104A, and the second shell half 100B may have a fourth tab 114B that extends from second side wall 104B. The second tab 114A of first shell half 100A may correspond to fourth tab 114B of second shell half 100B when first shell half 100A and second shell half 100B are brough into contact with each other. Each of first tab 112A, third tab 112B, second tab 114A, and fourth tab 114B may have an opening therein for the reception of a fastener, e.g., one or more interlocking clips 500 (see FIGS. 25-26). For instance, at least one interlocking clip 500 may be inserted within each of first tab 112A and third tab 112B, and at least one interlocking clip 500 may be inserted within each of second tab 114A and fourth tab 114B. In this manner, the first shell half 100A and the second shell half 100B may be locked and relative movement therebetween may be mitigated or precluded. In some aspects, first tab 112A, third tab 112B, second tab 114A, and fourth tab 114B may be manufactured using techniques other than additive manufacturing techniques, such as water jet cutting techniques, and may be secured to first shell half 100A and second shell half 100B using welding, adhesive, or other suitable techniques.

FIG. 8 illustrates a device 90, e.g., a nozzle, an electron beam, et cetera, applying a coating 95 in direction A to certain portions of blade 10. In some cases, and as depicted in FIG. 8, the protrusion 120 may directionally shield one or more sections of the blade 10, e.g., the trailing edge 31, during the coating process. The profile 120P of protrusion 120 may be configured to selectively shield certain portions of the blade 10 (e.g., may be configured to fully or partially shield trailing edge 31 of blade 10) from coating 95, and may also be configured to selectively direct or redirect coating 95 to other portions of blade 10. The profile 120P of the protrusion 120 may therefore allow a user to define and control the coating distribution pattern (i.e., the density and location of the coating 95) applied to the blade 10.

FIG. 8 shows the pressure side 26 of airfoil 12 divided into three regions-a trailing region 10T, a middle region 10M, and a leading region 10L. In an example, the profile 120P of protrusion 120 may be designed to allow for coating 95 to be applied by device 90 such that trailing region 10T receives less coating 95 than the leading region 10L. In some examples, the profile 120P of the protrusion 120 may be designed to allow for coating 95 to be applied such that trailing region 10T receives less coating 95 than the middle region 10M and the leading region 10L. Coating 95 may be selectively applied to various regions of the blade 10, and the amount of coating 95 applied to various regions of the blade 10 may be controlled. The distribution of coating 95 on various portions (e.g., leading region 10L, middle region 10M, and trailing region 10T) of the blade 10 may therefore be defined and controlled by altering the profile 120P of protrusion 120.

FIG. 8 shows the profile 120P of protrusion 120 has a generally trapezoidal shape. Such may allow for a particular distribution of coating 95 on the blade 10. The shape of the protrusion 120 may be changed to effectuate coating 95 having a different distribution or pattern. For example, the protrusion 120 may be made semi-circular, elliptical, polygonal, cylindrical, et cetera, as desired, to selectively apply coating 95 to blade 10 in the desired distribution. In some examples, the location and/or size of the protrusion 120 may also be altered in line with the desired distribution of the coating 95.

To determine a profile 120P of protrusion 120 that yields the desired coating distribution, a user may manufacture and test masking systems 100 having protrusions 120 with different profiles. This prototyping process may be arduous and costly when the masking systems 100 are manufactured using legacy manufacturing techniques (e.g., injection molding, sheet metal fabrication, investment casting, et cetera). Manufacturing the masking systems 100 using additive manufacturing techniques as discussed herein may allow for differently configured protrusions 120 to be tested quickly, cheaply, and efficiently to determine the profile 120P of protrusion 120 that is optimal for the application at hand.

While the masking system 100 depicted herein uses the protrusion 120 to mask or cover trailing edge 31 of blade 10, in some examples, the protrusion 120 may alternately or additionally be configured to mask or cover the leading edge 29 of blade 10. In some examples, a protrusion (e.g., protrusion 120) may selectively mask or cover each of the leading edge 29 and trailing edge 31, and these two protrusions may collectively control the distribution pattern of the coating 95 on the various surfaces of blade 10. Further, while the figures show the protrusion 120 disposed on second shell half 100B, one or more protrusions may likewise extend from first shell half 100A or another portion of masking system 100.

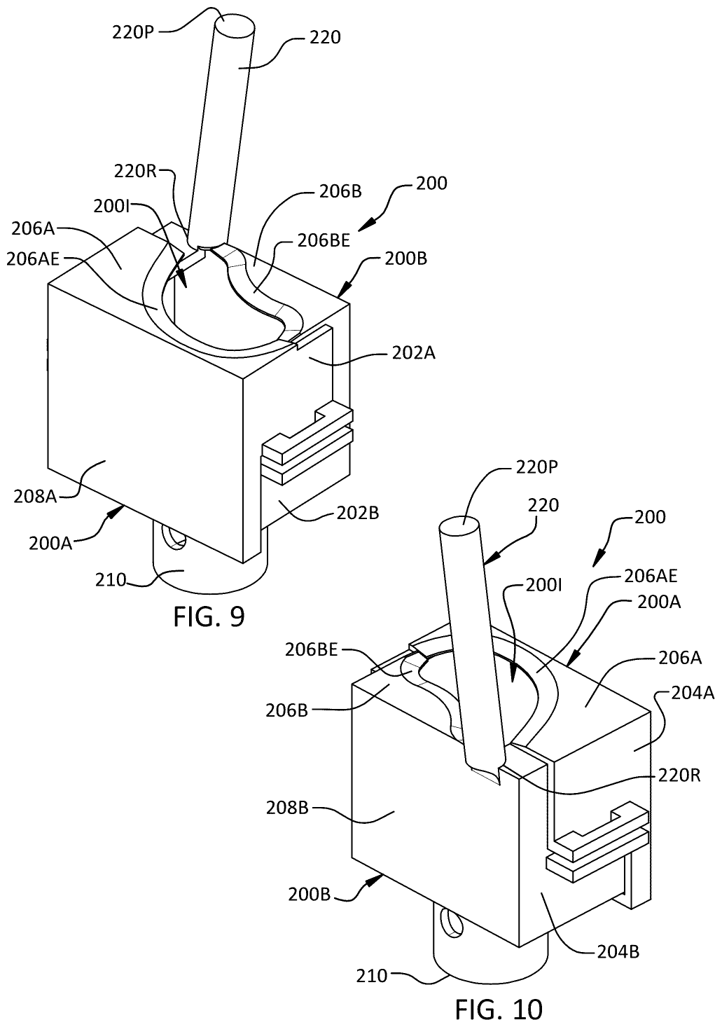

FIGS. 9-12 show a masking system 200 in another aspect of the disclosure. The masking system 200 may be similar to masking system 100, except as noted and/or shown. Corresponding parts may be denoted with corresponding reference numerals, though with any noted deviations. One difference between masking system 200 and masking system 100 may be that masking system 200 may have a protrusion 220 having a profile 220P that differs from the profile 120P of protrusion 120 of masking system 100. In the example illustrated in FIG. 9, the profile 220P of protrusion 220 is shown to be spherical. As discussed, protrusion 220 with a spherical profile 220P may result in a coating gradient or distribution that is different from a coating gradient or distribution produced by the protrusion 120 having the profile 120P.

In non-limiting aspects of the disclosure, masking system 200 may have a first shell half 200A and a second shell half 200B. First shell half 200A and second shell half 200B may be brought together to encapsulate a portion of the blade 10 within an interior 200I of first shell half 200A and second shell half 200B. First shell half 200A and second shell half 200B may be secured to each other to retain a component therein. The masking system 200 may further include a protrusion 220 that extends from one of the first shell half 200A and the second shell half 200B. The masking system 200 may be configured to selectively shield, cover, or protect one or more portions of the blade 10.

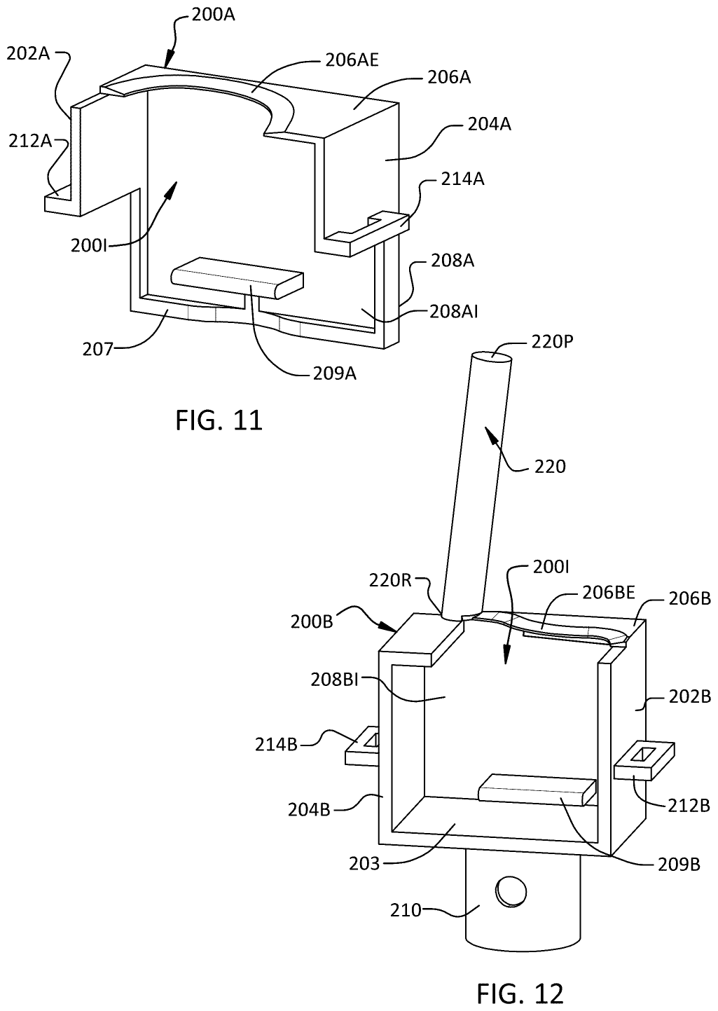

In the embodiment illustrated in FIGS. 11 and 12, the first side wall 202A and second side wall 204A of first shell half 200A may extend over and overlap one or more portions of the second shell half 200B. For example, first side wall 202A of first shell half 200A may extend over and overlap first side wall 202B of second shell half 200B, and second side wall 204A of first shell half 200A may extend over and overlap second side wall 204B of second shell half 200B, when first shell half 200A and second shell half 200B are brought into contact with each other. Overlapping side walls may provide for a suitable seal as the blade 10 retained within the masking system 200 undergoes a finishing process, such as a coating process. An improper seal may allow coating material to penetrate the masking system 200 and improperly coat portions of the blade 10 not intended to be coated.

The first shell half 200A may have a first side wall 202A, a second side wall 204A opposing first side wall 202A, a top wall 206A extending laterally between first side wall 202A and second side wall 204A, and an end wall 208A extending vertically between first side wall 202A and second side wall 204A. The top wall 206A may have an edge 206AE that has a shape which generally corresponds to a profile of the blade 10, e.g., the shape of edge 206AE shape may generally correspond to a profile of airfoil 12 (e.g., on the suction side 27) of blade 10. In some aspects, edge 206AE may be tapered.

The first shell half 200A may include a lip 207 which extends from one or more of first side wall 202A, second side wall 204A, top wall 206A, and/or end wall 208A. The first shell half 200A may further include a shelf 209A that extends from an interior 208AI of end wall 208A. The shelf 209A may assist in retaining the component within the masking system 200, e.g., by contacting the dovetail 18 of a blade 10 seated in the interior 200I.

The second shell half 200B (see FIGS. 10 and 12) may have a first side wall 202B, a second side wall 204B opposing first side wall 202B, a top wall 206B, an end wall 208B vertically extending between first side wall 202B and second side wall 204B, a bottom wall 203 extending laterally between first side wall 202B and second side wall 204B and opposing top wall 206B, and a mounting portion 210 extending from bottom wall 203. The top wall 206B may have an edge 206BE that has a shape which generally corresponds to a profile of the blade 10. For example, the shape of edge 206BE may generally correspond to a profile of the airfoil 12 (e.g., on the pressure side 26) of the blade 10. In some aspects, edge 206BE may be tapered.

The second shell half 200B may further include protrusion 220 having profile 220P. The protrusion 220 may extend from a protrusion base 220R located on top wall 206B. In some aspects, the protrusion base 220R may be located at or along edge 206BE. The second shell half 200B may further include a shelf 209B that extends from an interior 208BI of end wall 208B. The shelf 209B may assist in retaining the blade 10 within the masking system 200, e.g., by contacting dovetail 18 of the blade 10 seated in interior 200I.

The mounting portion 210 may be usable for securing the masking system 200 to a stabilizing structure (not shown, e.g., a table, a tool, a vice, et cetera) to prevent undue motion of masking system 200 during operation, such as while performing a finishing process on the blade 10 retained within masking system 200. The mounting portion 210 may have any suitable arrangement and number of openings, slots, apertures, et cetera, to allow for the masking system 200 to be coupled to the stabilizing structure.

To allow for securement of second shell half 200B to first shell half 200A, the first shell half 200A may have a first tab 212A (FIG. 11) that extends from first side wall 202A and the second shell half 200B may have a third tab 212B (FIG. 12) that extends from first side wall 202B. The first tab 212A of first shell half 200A may correspond to third tab 212B of second shell half 200B when first shell half 200A and second shell half 200B are brought into contact with each other. In some examples, the first shell half 200A may further include a second tab 214A extending from second side wall 204A, and the second shell half 200B may have a fourth tab 214B extending from second side wall 204B. The second tab 214A of first shell half 200A may correspond to fourth tab 214B of second shell half 200B when first shell half 200A and second shell half 200B are brought into contact with each other. Each of first tab 212A, third tab 212B, second tab 214A, and fourth tab 214B may have an opening therein for the reception of a fastener, e.g., one or more interlocking clips 500 (see FIGS. 25-26). For instance, at least one interlocking clip 500 may be inserted within each of first tab 212A and third tab 212B, and at least one interlocking clip 500 may be inserted within each of second tab 214A and fourth tab 214B. In this manner, the first shell half 200A and the second shell half 200B may be locked and relative movement therebetween may be mitigated or precluded. In some aspects, first tab 212A, third tab 212B, second tab 214A, and fourth tab 214B may be manufactured using techniques other than additive manufacturing techniques, such as water jet cutting techniques, and may be secured to first shell half 200A and second shell half 200B using welding.

As shown in FIG. 8 with respect to masking system 100, the masking system 200 may likewise house blade 10 such that protrusion 220 selectively masks trailing edge 31 of blade 10. In some examples, the protrusion 220 may alternately or additionally be configured to mask or cover the leading edge 29 of blade 10. In some examples, a protrusion (e.g., protrusion 220) may selectively mask or cover each of the leading edge 29 and trailing edge 31, and these two protrusions may collectively control the distribution pattern of the coating 95 on the various surfaces of blade 10. Further, while the figures show the protrusion 220 disposed on second shell half 200B, one or more protrusions may likewise extend from first shell half 200A or another portion of masking system 200. The profile 220P of protrusion 220 of masking system 200 may provide for a different coating distribution on blade 10 as compared to profile 120P of protrusion 120 of masking system 100.

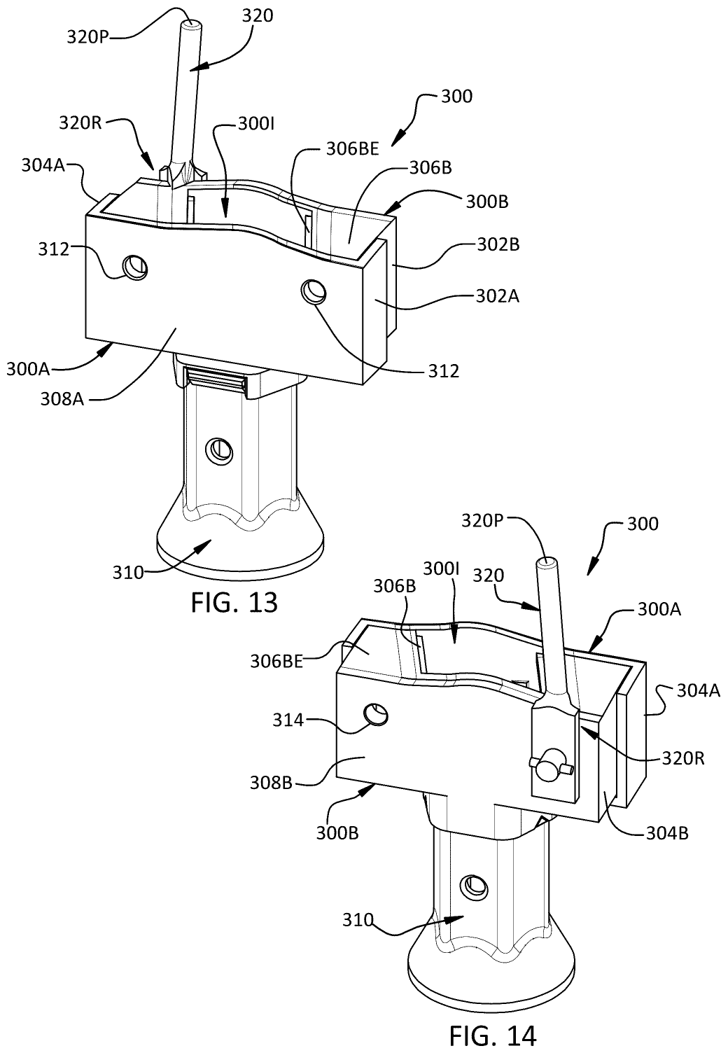

FIGS. 13-21 show a masking system 300 or components thereof in another aspect of the disclosure. The masking system 300 may be similar to masking system 100, except as noted and/or shown. Corresponding parts may be denoted with corresponding reference numerals, though with any noted deviations. One difference between masking system 300 and masking system 100 may be that masking system 300 may have a protrusion 320 having a profile 320P that differs from the profile 120P of protrusion 120 of masking system 100. In the example illustrated in FIG. 13, the profile 320P may be spherical. As discussed, a protrusion 320 with a spherical profile 320P may result in a coating gradient or distribution that is different from a coating gradient or distribution produced by protrusion 120 having profile 120P. Another difference between masking system 300 and masking system 100 may be that masking system 300 may have one or more detachable parts. For example, masking system 300 may have a mounting handle 310 that may be readily detachable from the rest of masking system 300, e.g., a second shell half 300B thereof. Further, protrusion 320 may also be readily detachable from the rest of masking system 300, e.g., a second shell half 300B thereof. The detachability of parts of masking system 300, such as the mounting handle 310 and the protrusion 320, may allow for these parts to be readily replaced, e.g., when they are in need of repair, without having to fabricate an entirely new masking system 300. Furthermore, protrusion 320 may be readily replaced with another protrusion 320 having a different profile than the profile 320P, and therefore, the distribution of coating on the blade 10 may be changed without having to replace the entire masking system 300.

In the embodiment illustrated in FIGS. 13 and 14, a first side wall 302A and a second side wall 304A of first shell half 300A may extend over and overlap one or more portions of the second shell half 300B. One or more first apertures 312 for the reception of fasteners, e.g., a pin, may be arranged at or on first shell half 300A, and one or more second apertures 314 for the reception of fasteners, e.g., a pin, may be arranged on second shell half 300B. The apertures 312 and 314 may be usable with one or more fasteners to secure the first shell half 300A and the second shell half 300B together during a finishing process to prevent motion of the first shell half 300A relative to the second shell half 300B.

As shown in FIGS. 13-18, masking system 300 may have a first shell half 300A and a second shell half 300B. First shell half 300A (see FIGS. 13-17) may have a first side wall 302A, a second side wall 304A opposing first side wall 302A, a bottom wall 303A extending laterally between first side wall 302A and second side wall 304A, and an end wall 308A extending vertically between first side wall 302A and second side wall 304A. The first shell half 300A may further include a shelf 309A that extends from an interior 308AI of end wall 308A. The shelf 309A may assist in retaining the component within masking system 300, e.g., by contacting the dovetail 18 of a blade 10 seated in interior 300I.

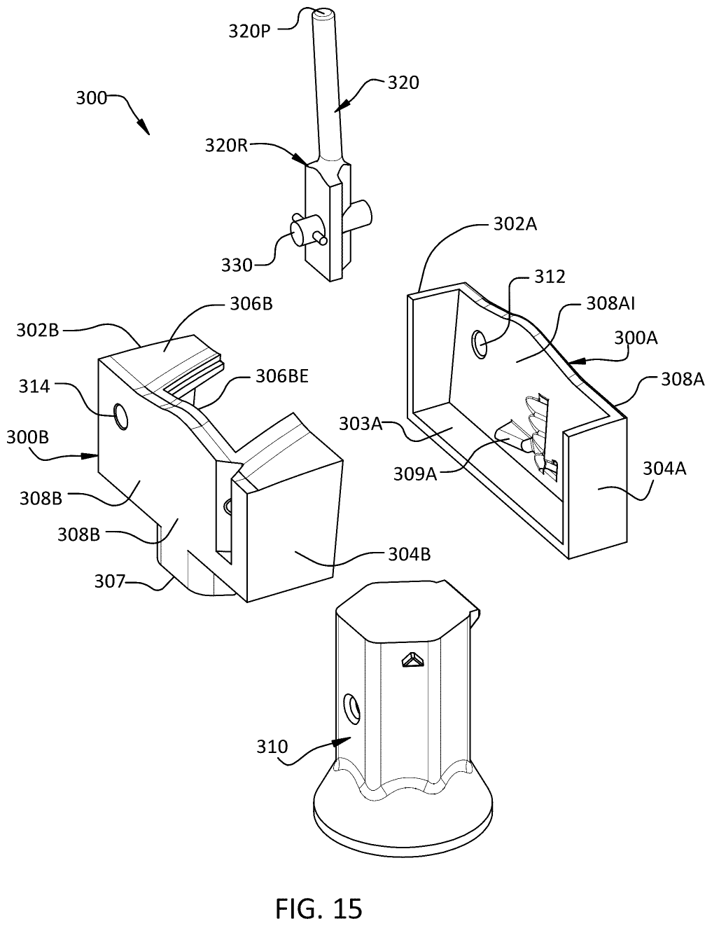

The second shell half 300B (see FIGS. 15 and 18) may have a first side wall 302B, a second side wall 304B opposing first side wall 302B, a top wall 306B extending laterally between first side wall 302B and second side wall 304B, an end wall 308B extending vertically between first side wall 302B and second side wall 304B, a bottom wall 303B extending laterally between first side wall 302B and second side wall 304B, and a mounting portion 307 extending from bottom wall 303B. The top wall 306B, in some aspects, may have an edge 306BE that has a shape which generally corresponds to the blade 10, e.g., the shape of the edge 306BE may generally correspond to a profile of the platform 16 of the blade 10. The second shell half 300B may include a shelf 309B (FIG. 18) that extends from an interior 308BI of end wall 308B. The shelf 309B may assist in retaining the component within the masking system 300, e.g., by contacting dovetail 18 of a blade 10 seated in the interior 300I.

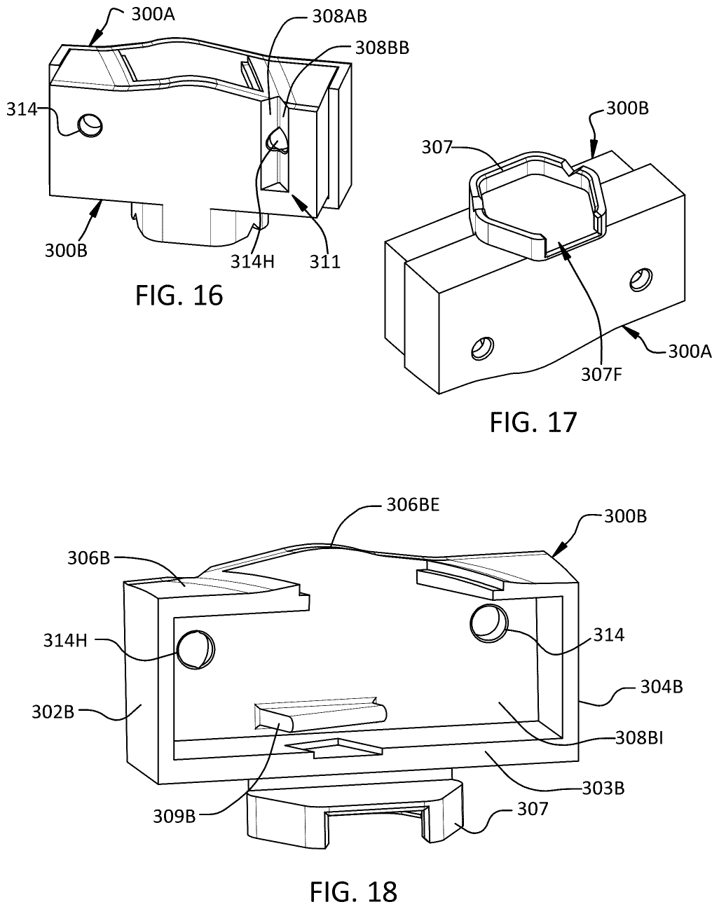

In some examples, the second shell half 300B may include a notch 311 (see FIG. 16) having a first face 308AB and a second face 308BB forming a generally V-shape and configured to receive protrusion 320. A hole 314H may be extend through first face 308AB and second face 308BB for the reception of a fastener, e.g., a pin 330 (FIG. 15).

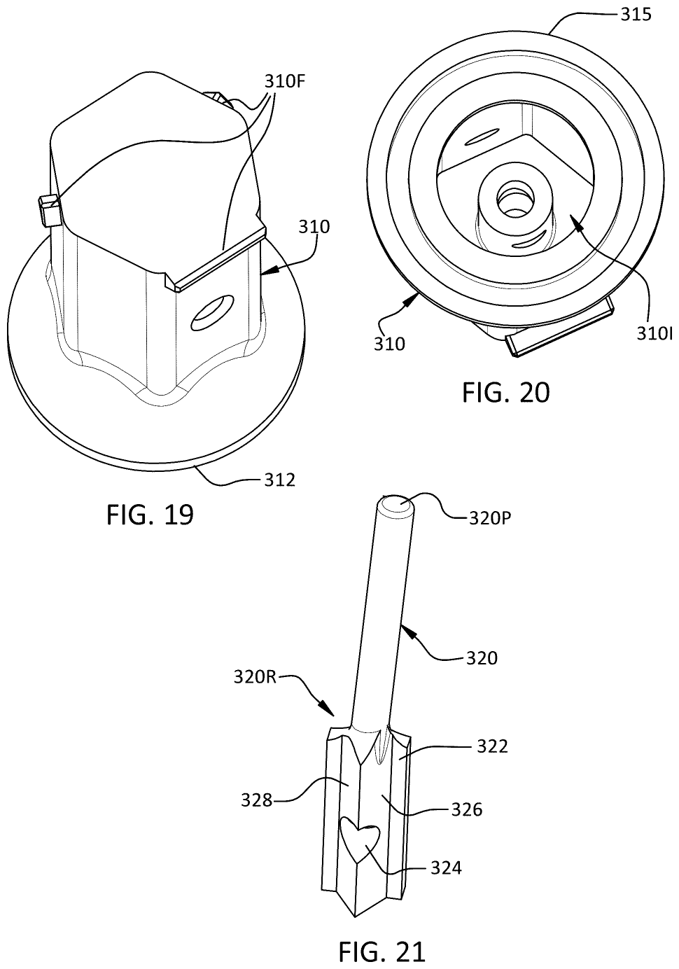

The mounting portion 307 may be usable for securing masking system 300 to a mounting handle 310 to prevent motion of masking system 300 during operation. The mounting handle 310 and the mounting portion 307 may have any suitable arrangement and number of openings, slots, apertures, tabs, et cetera, to allow the mounting handle 310 to be coupled to the mounting portion 307. For example, the mounting portion 307 may have features 307F (FIG. 17), e.g., slots, depressions, et cetera, which correspond to features 310F (FIG. 19), e.g., tabs, extensions, et cetera, of the mounting handle 310 for operable coupling therebetween. The mounting handle 310 may, in some examples, include a flared base 315 (FIG. 20). In some examples, as depicted in FIG. 20, the mounting handle 310 may have a hollow interior 310I. The mounting handle 310 may be detachable from the rest of masking system 300 such that the mounting handle 310 may be readily replaced, e.g., in case mounting handle 310 is damaged.

The protrusion 320 (FIG. 21) may be a detachable, replaceable part which may be coupled to a portion of masking system 300, e.g., to the second shell half 300B. The protrusion 320 may have profile 320P, and may extend from a protrusion base 320R of the protrusion 320. A mountable base 322 may extend from protrusion base 320R opposite protrusion 320. The mountable base 322 may have faces 326 and 328 and an aperture 324 extending through the faces 326 and 328. Collectively, the faces 326 and 328 may generally form a shape (e.g., a V-shape) corresponding to the V-shape formed by first face 308AB and second face 308BB (FIG. 16) of the second shell half 300B. The aperture 324 may be configured to receive a fastener, e.g., a pin 330 (see FIG. 15), such that the fastener may operable secure the protrusion 320 to the rest of masking system 300. The mountable base 322 may be mounted to second shell half 300B, e.g., may be disposed within notch 311, such that aperture 324 of mounting base 322 aligns with hole 314H in second shell half 300B. A fastener, e.g., pin 330, may be removably inserted through aperture 324 and hole 314H to secure mountable base 322 to second shell half 300B. The mountable base 322 may be disassociated from second shell half 300B by removing pin 330. The removable mountable base 322 may allow for different protrusions 320 having disparate profiles to be associated with masking system 300.

As shown in FIG. 8 with respect to masking system 100, masking system 300 may encapsulate blade 10 such that protrusion 320 masks trailing edge 31 of blade 10 and controls the distribution of coating 95 on blade 10. In some examples, the protrusion 320 may alternately or additionally be configured to mask or cover the leading edge 29 of blade 10. In some examples, protrusions may selectively mask or cover each of the leading edge 29 and trailing edge 31, and these two protrusions may collectively control the distribution pattern of the coating on the various surfaces of blade 10. Further, while the figures show the protrusion 320 disposed on second shell half 300B, one or more protrusions may likewise extend from first shell half 300A or another portion of masking system 300.

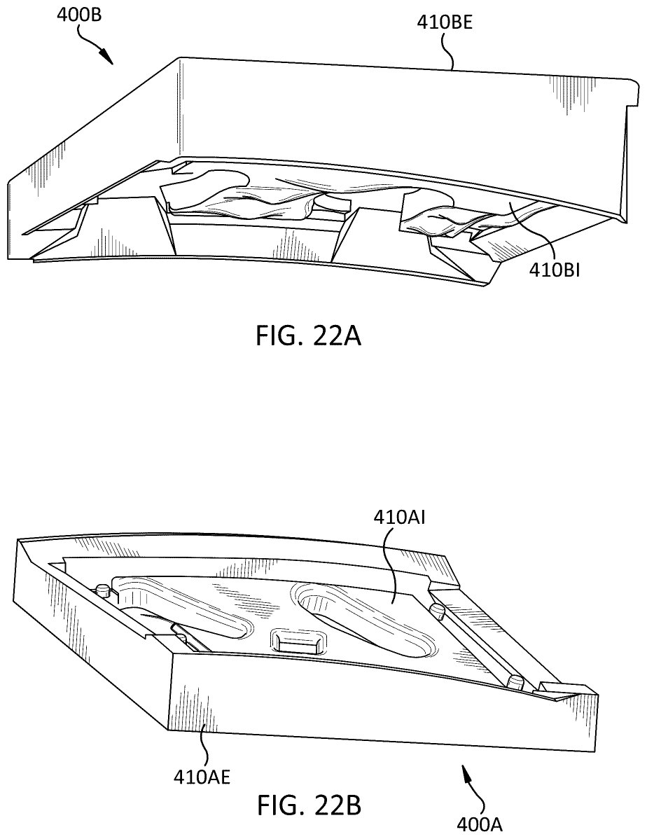

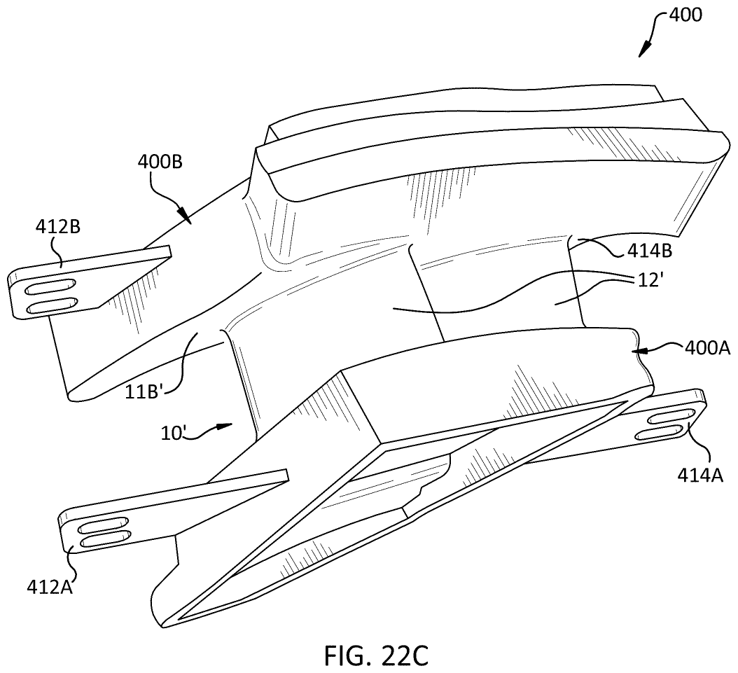

Focus is now directed to FIGS. 22A-24B, which depict a masking system 400 or portions thereof for covering or protecting one or more surfaces, e.g., non-gas path surfaces, of a vane 10′ during a finishing process. In some aspects, the masking system 400 may include a first shell 400A (FIG. 22B) configured to shield the top surface 11T′ (FIG. 2) and perimeter 11P′ of top platform 11′, and a second shell 400B (FIG. 22A) configured to shield the bottom surface 13B′ and perimeter 13P′ of the bottom platform 13′. FIG. 22C shows the masking system 400, i.e., the first shell 400A and second shell 400B thereof, covering non-gas path surfaces of vane 10′ such that airfoils 12′ of vane 10′ are exposed.

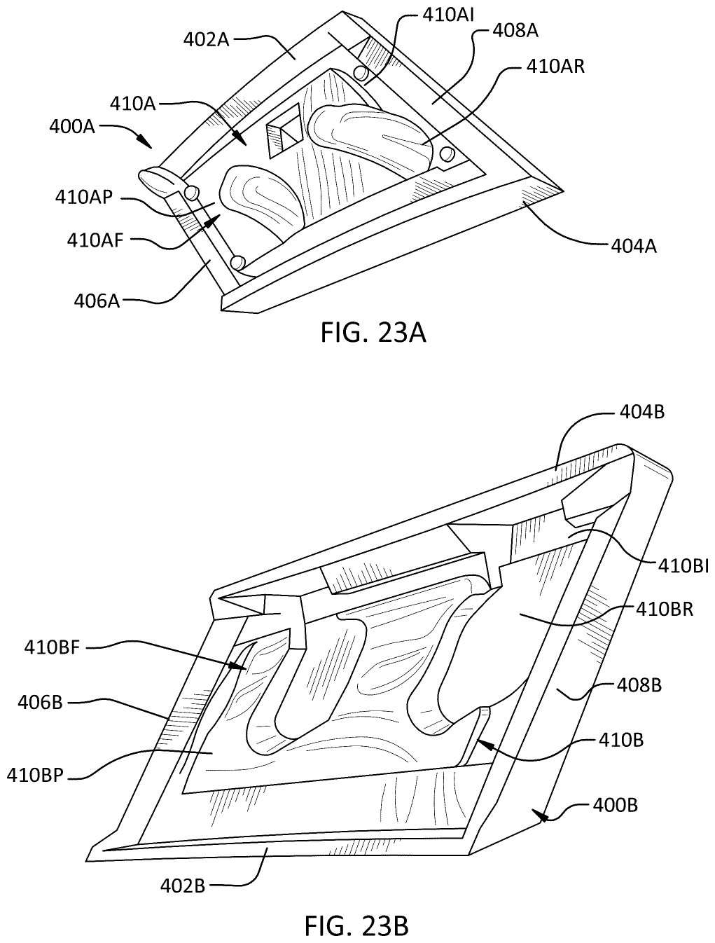

The first shell 400A may include a first side wall 402A (FIG. 23A), a second side wall 404A opposing first side wall 402A, a first end wall 406A, a second end wall 408A opposing first end wall 406A, and a cover 410A extending between each of first side wall 402A, second side wall 404A, first end wall 406A, and second end wall 408A. The first side wall 402A, second side wall 404A, first end wall 406A, and second end wall 408A may extend out from cover 410A and may be configured to shield the perimeter 11P′ of the top platform 11′ of vane 10′. The cover 410A may have an interior surface 410AI that has features 410AF corresponding to top surface 11T′ of the top platform 11′. For example, the features 410AF may include one or more peaks 410AP and one or more recesses 410AR that correspond to the geometry of the top surface 11T′ of the top platform 11′ such that the interior surface 410AI may mate with the top surface 11T′ of the top platform 11′.

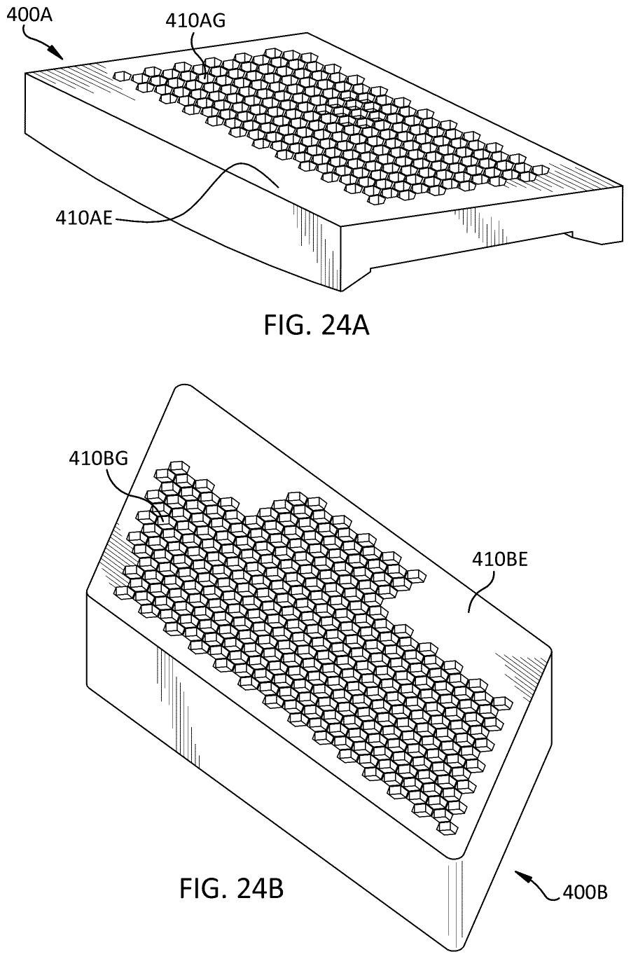

The first shell 400A may further include an exterior surface 410AE (FIG. 24A) opposing the interior surface 410AI. The exterior surface 410AE may, in some aspects of the disclosure, have a grid 410AG formed therein. The grid 410AG formed in the first shell 400A may reduce the weight of the first shell 400A. The grid 410AG may be, but is not limited to, a hex grid pattern.

In some aspects, first shell 400A may further include a first tab 412A (FIG. 22C) and second tab 414A extending from first side wall 402A, second side wall 404A, first end wall 406A, and/or second end wall 408A. The first tab 412A and second tab 414A may be usable with one or more fasteners, e.g., wire tires, for the securement of the first shell 400A to the second shell 400B such that the vane 10′ is securely retained within the masking system 400.

The second shell 400B (FIG. 23B) may include a first side wall 402B, a second side wall 404B opposing first side wall 402B, a first end wall 406B, a second end wall 408B opposing first end wall 406B, and a cover 410B extending between each of first side wall 402B, second side wall 404B, first end wall 406B, and second end wall 408B. The first side wall 402B, second side wall 404B, first end wall 406B, and second end wall 408B may extend out from the cover 410B and may be configured to shield the perimeter 13P′ of the bottom platform 13′ when secured to vane 10′. The cover 410B may have an interior surface 410BI that has features 410BF corresponding to the bottom surface 13B′ of the bottom platform 13′. For example, the features 410BF may include one or more peaks 410BP and one or more recesses 410BR that correspond to a geometry of the bottom surface 13B′ of vane 10.′

The second shell 400B may further include an exterior surface 410BE (FIG. 24B) opposing the interior surface 410BI that, in some aspects, may have a grid 410BG formed therein. The grid 410BG may be a pattern formed in the second shell 400B that reduces the weight of second shell 400B. The grid 410BG may be, but is not limited to, a hex grid pattern. In some aspects, the second shell 400B may further include third tab 412B and fourth tab 414B (FIG. 22C) extending from first side wall 402B, second side wall 404B, first end wall 406B, and/or second end wall 408B. The third tab 412B and fourth tab 414B may be usable with one or more fasteners, e.g., wire tires, for the securement of the masking system 400 during the finishing process. For example, a wire tie or other fastener may be used to secure each of first tab 412A and third tab 412B, and another wire tie or fastener may be used to secure each of second tab 414A and fourth tab 414B, to secure vane 10′ to masking system 400.

In some aspects, the masking system, e.g., the masking system 100, 200, 300, and 400, may be additively manufactured. Additive manufacturing, also referred to as 3D printing, may be performed by dividing the shape of a three-dimensional object, e.g., the masking system 100, 200, 300, or 400, into a number of two-dimensional cross sections having a uniform or variable thickness, and forming the two-dimensional cross sections to be stacked one by one. For example, the masking systems 100, 200, 300, or 400, or portions thereof, may be additively manufactured using binder jetting, sheet lamination, direct metal laser sintering (DLS), metal digital light processing (DLP), powder bed fusion method, directed energy deposition (DED), et cetera. Any one or more of these methods, or any other additive manufacturing method, now known or hereinafter developed, may be employed to manufacture masking systems 100, 200, 300, and/or 400. The material used for the additive manufacturing process may be any suitable material, now known or subsequently developed, that can withstand a high-temperature process reaching temperatures above about 260° C., and in some examples, up to about 1100° C. In some non-limiting examples, the masking systems 100, 200, 300, and/or 400 described herein may be manufactured using materials such as an alloy, e.g., a nickel-based super alloy or other alloy. One example of a nickel-based super alloy that may be used in the additive manufacturing process may be Hastelloy® X produced by Haynes international, based in Kokomo, Indiana, or other suitable materials.

In some non-limiting examples, masking system 100, masking system 200, masking system 300, and/or masking system 400 may be manufactured using laser powder bed fusion. The laser powder bed fusion method may involve using an energy beam, e.g., a laser, on specific points of a bed of metal powder. The energy beam may heat the metal powder until the metal powder reaches or exceeds a melting temperature of the metal powder. The metal powder may then melt and fuse into the desired shape. Once a layer is complete, the bed in which the metallic powder is deposited on may be moved, e.g., lowered, to create room for additional material to be placed on the previously melted layers (e.g., on the already fused portions) for the next layer of the design. The energy beam may be directed through the use of a CAD or other computer design file.

Additively manufacturing masking systems described herein may provide several benefits. For example, additive manufacturing may be more efficient and cost-effective relative to conventional manufacturing techniques (e.g., injection molding, sheet metal fabrication, et cetera). Further, additive manufacturing may allow for complex shape geometries such as curves, contours, and fillets to be readily manufactured, and the additively masking systems may therefore suitably cover those portions of components (e.g., the blade 10, vane 10′, or other components) that are not intended to undergo the finishing process (e.g., high-temperature finishing process). Furthermore, since the additively manufactured masking systems may better fit the components they are intended to selectively cover, the need for the use of an additional slurry injection when shielding the component may be circumvented.

Further, additive manufacturing, because of its efficiency and cost-effective nature, may allow a user to readily reconfigure and optimize the masking systems 100, 200, 300, and/or 400. For example, several different protrusions 120 having different shapes and sizes may be readily additively manufactured to achieve different distributions of coating 95 on blade 10.

FIGS. 25 and 26 show the interlocking clips 500 in more detail. The interlocking clips 500 may be used to secure together, for example, the first shell half 100A and the second shell half 100B of masking system 100. The interlocking clips 500 may include an outer clip 510 and an inner clip 550 which are both inserted into, for example, the second tab 114A and fourth tab 114B of the masking system 100, as depicted in FIG. 25. When the interlocking clips 500 are inserted in this fashion, they may serve to lock the first shell half 100A to the second shell half 100B such that there is no relative movement therebetween.

The second tab 114A and fourth tab 114B of masking system 100 are shown in more detail in FIG. 26. The second tab 114A may include a first slot (or opening) 615 defined by walls 617 and 619, and fourth tab 114B may include a second slot (or opening) 625 defined by walls 627 and 629. As discussed herein, the interlocking clips 500, i.e., each of the outer clip 510 and the inner clip 550, may be passed through each of first slot 615 and second slot 625 to temporarily secure first shell half 100A and second shell half 100B. Once the finishing process is completed, a user may extract the interlocking clips 500 from the first slot 615 and second slot 625 to release the first shell half 100A from the second shell half 100B and liberate the component therein.

In more detail, the outer clip 510 may be inserted into the first slot 615 and second slot 625 of the tabs, e.g., the second tab 114A and fourth tab 114B, such that the outer clip 510 contacts the walls 617 and 619 of the second tab 114A and walls 627 and 629 of the fourth tab 114B. The outer clip 510 may be configured to matingly accept the inner clip 550. The inner clip 550 may be received by the outer clip 510 therein and the inner clip 550 may push the outer clip 510 outwards against the walls 617 and 619 of the second tab 114A and the walls 627 and 629 of the fourth tab 114B. In implementations, a tool, such as a vice grip, may be used to further push the outer clip 510 and the inner clip 550 towards the walls 617 and 619 of the second tab 114A and the walls 627 and 629 of the fourth tab 114B to cause the tabs of the masking system to be secured to each other such that there is minimal or no relative movement between the tabs. When the finishing process is complete, outer clip 510 and inner clip 550 may be disassociated from each other and second tab 114A and fourth tab 114B using, e.g., a pair of pliers or other tool. For instance, outer clip 510 and inner clip 550 may be collectively pulled out of first slot 615 and second slot 625, and outer clip 510 and inner clip 550 may be disassociated from each other. This unlocking of interlocking clips 500 may be non-destructive and clips 510 and 550 may be reused to subsequently lock the same or a different masking system.

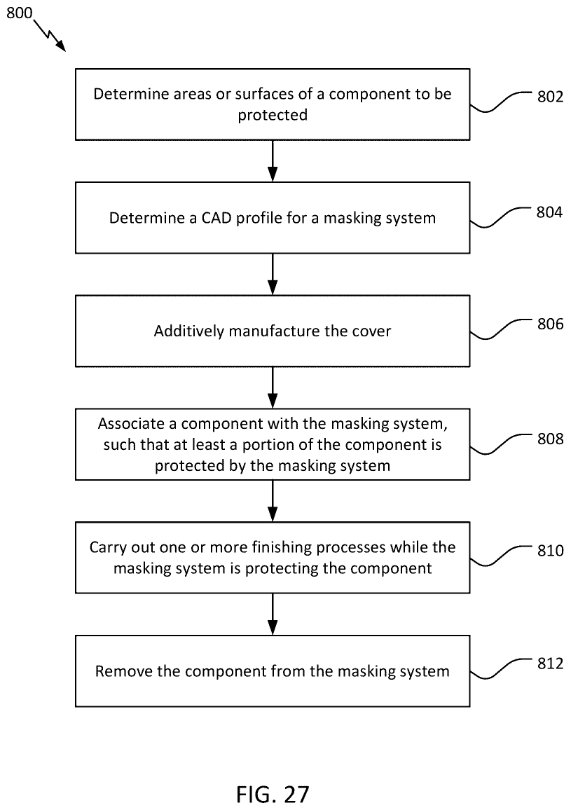

FIG. 27 shows a flowchart illustrating a method 800 of making and using a masking system, such as the masking system 100, 200, 300, or 400. At step 802, the areas or surfaces of a component to be covered during a finishing process are determined. For example, at step 802, it may be determined that all of the non-gas path surfaces of a gas turbine component are to be covered. In some examples, where the finishing process is a coating process, a desired distribution of coating on the component may also be determined.

At step 804, a design profile of the masking system, e.g., the masking system 100, 200, 300, or 400, may be developed using, for example, CAD software. At step 806, the masking system, e.g., masking system 100, 200, 300, or 400, may be additively manufactured. At step 808, a component, e.g., a gas turbine component, may be associated with the masking system such that at least a portion of the component is protected by the masking system. For example, the dovetail 18 of the blade 10 may be placed inside the masking system 100, 200, or 300 for protection from coating 95. At step 810, one or more finishing processes may be used to impact exposed portions of the component while the remainder of the component is protected by the masking system. For example, the exposed airfoil 12 of the blade 10 may be coated, machined, deburred, or otherwise finished while the dovetail 18 is shielded by the masking system 100, 200, or 300. Once the finishing is complete, the component (e.g., blade 10) may be disassociated from the masking system at step 812. If required, the portion of the component that was shielded by the masking system may now be finished to prepare the component for operation.

Thus, as has been described, masking system 100, masking system 200, masking system 300, and masking system 400 may protect one or more portions of a component, e.g., a gas turbine component, while one or more exposed portions of the component undergo one or more finishing processes, e.g., a high temperature finishing process. While the masking system embodiments described herein are depicted as being used with a component that is a gas turbine component, e.g., the blade 10 and the vane 10′, the artisan would understand the masking systems disclosed herein may be readily adapted for use with other components that are to be selectively masked, e.g., when undergoing a finishing process such as a high-temperature coating process.

Many different arrangements of the various components depicted, as well as components not shown, are possible without departing from the spirit and scope of the present disclosure. Embodiments of the present disclosure have been described with the intent to be illustrative rather than restrictive. Alternative embodiments will become apparent to those skilled in the art that do not depart from its scope. A skilled artisan may develop alternative means of implementing the aforementioned improvements without departing from the scope of the present disclosure.

It will be understood that certain features and subcombinations are of utility and may be employed without reference to other features and subcombinations and are contemplated within the scope of the claims. Not all steps listed in the various figures need be carried out in the specific order described.

The disclosure claimed is:

1. A masking system for selectively masking a component, the masking system comprising:
a first shell half;
a second shell half configured to be secured to the first shell half such that at least a portion of the first shell half overlaps the second shell half when the component is retained by the masking system; and
a protrusion extending from one of the first shell half and the second shell half, the protrusion configured to cover an edge of the component.

2. The masking system of claim 1, wherein the protrusion is configured to be removable.

3. The masking system of claim 1 configured to retain the component for a coating process.

4. The masking system of claim 3, wherein a distribution of coating on the component is defined via a profile of the protrusion.

5. The masking system of claim 3, wherein the first shell half has a first tab, and the second shell half has a second tab that corresponds to the first tab when the first shell half is brought into contact with the second shell half.

6. The masking system of claim 5, including a fastener extending through each of the first tab and the second tab.

7. The masking system of claim 5, including interlocking clips extending through each of the first tab and the second tab.

8. The masking system of claim 1, wherein the masking system is additively manufactured.

9. The masking system of claim 8, wherein the component is a component of a gas turbine.

10. The masking system of claim 9, wherein:
the component is a gas turbine blade; and
the edge is a trailing edge of the gas turbine blade.

11. The masking system of claim 10, wherein the masking system is configured to mask at least a dovetail of the gas turbine blade.

12. The masking system of claim 1, wherein the first shell half includes a first shelf, and the second shell half includes a second shelf, each of the first shelf and the second shelf configured to contact the component.

13. The masking system of claim 1, wherein the masking system further includes a mounting portion for mounting the masking system to a surface.

14. The masking system of claim 13, wherein the mounting portion is removably coupled to one of the first shell half and the second shell half.

15. An additively manufactured masking system for selectively masking a blade of a gas turbine for a coating process, the masking system comprising:
a first shell half having a wall corresponding to a suction side of the blade;
a second shell half having a wall corresponding to a pressure side of the blade; and
a protrusion extending from one of the first shell half and the second shell half;
wherein, a distribution of coating on the blade during the coating process is defined via a profile of the protrusion.

16. The additively manufactured masking system of claim 15, wherein the protrusion is removable.

17. The additively manufactured masking system of claim 15, wherein the protrusion has a generally spherical shape.

18. The additively manufactured masking system of claim 15, wherein the protrusion has a generally trapezoidal shape.

19. A masking system for selectively masking a component, the masking system comprising:
a first shell having a first cover and a first tab, the first cover having at least a first recess and a first peak, each of the first recess and the first peak corresponding to the component at a first side thereof; and
a second shell having a second cover and a second tab, the second cover having at least a second recess and a second peak, each of the second recess and the second peak corresponding to the component at a second side thereof, the second side opposing the first side.

20. The masking system of claim 19, wherein the component is a gas turbine vane.
